(19) United States
(12) Patent Application Publication
(10) Pub. No.: US 2010/0102725 A1
(43) Pub. Date: Apr. 29, 2010

(54) HIGH-VOLTAGE PULSE GENERATOR AND HIGH-PRESSURE DISCHARGE LAMP COMPRISING SUCH A GENERATOR

(75) Inventors: Andreas Kloss, Neubiberg (DE); Bernhard Schalk, Eching (DE); Steffen Walter, Oberpframmern (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/529,745

(22) PCT Filed: Mar. 5, 2008
(86) PCT No.: PCT/EP2008/052642

§ 371 Date: Sep. 3, 2009

(30) Foreign Application Priority Data
Mar. 6, 2007 (DE) 10 2007 010 898.4

(51) Int. Cl. H01J 7/44; H03K 3/00

(52) U.S. Cl. 315/51; 307/106; 315/56

(57) ABSTRACT

A compact high-voltage pulse generator based on a spiral pulse generator, the spiral pulse generator being in the form of an LTCC component part or HTCC component part including a ceramic film wound in the form of a spiral and metallic conductive paste applied thereto in strip form, wherein the spiral pulse generator acts as a transformer by virtue of a first metallic conductor being rolled up to form a spiral with n turns, where n is at least 5, while in addition a switch and a charging capacitor are connected to the start of the first metallic conductor.

### TECHNICAL FIELD

The invention is based on a high-voltage pulse generator in accordance with the pre-characterizing clause of claim 1. Such generators can be used in particular for starting high-pressure discharge lamps for general lighting or for photooptical purposes or for motor vehicles. The invention furthermore relates to a high-pressure discharge lamp including such a generator.

### PRIOR ART

The problem of starting high-pressure discharge lamps is at present solved by virtue of the fact that the starting gear is integrated in the ballast. One disadvantage with this is the fact that the feed lines need to be designed to be resistant to high voltages.

In the past, repeated attempts have been made to integrate the starting unit in the lamp. These attempts have included attempts to integrate the starting unit in the base. Particularly effective starting which promises high pulses has been successful by means of so-called spiral pulse generators; see U.S. Pat. No. 3,289,015. A relatively long time ago, such devices were proposed for various high-pressure discharge lamps such as metal-halide lamps or sodium high-pressure lamps; see U.S. Pat. No. 4,325,004, U.S. Pat. No. 4,353,012, for example. However, they could not gain acceptance since, firstly, they are too expensive. Secondly, the advantage of incorporating them in the base is insufficient since the problem of supplying the high voltage into the bulb remains. For this reason, the probability of damage to the lamp, whether it be insulation problems or a breakdown in the base, increases severely. Starting devices which have been conventional to date generally could not be heated to above 100° C. The voltage produced would then have to be supplied to the lamp, which requires lines and lamp holders with a corresponding high-voltage strength, typically approximately 5 kV.

A dual generator can be used for producing particularly high voltages; see U.S. Pat. No. 4,608,521.

### DESCRIPTION OF THE INVENTION

The object of the present invention is to specify a spiral pulse generator which can be used as a transformer which withstands high temperatures.

This object is achieved by the characterizing features of claim 1.

A further object is to provide a high-pressure discharge lamp with a considerably improved starting response in comparison with previous lamps and with which there is no danger of any damage as a result of the high voltage. This applies in particular to metal-halide lamps, where the material of the discharge vessel can be either quartz glass or ceramic.

This object is achieved by the characterizing features of claim 10.

Particularly advantageous configurations are given in the dependent claims.

DE-Az 102005061832.4 and 102005061831.6 have disclosed a compact high-voltage pulse generator which can produce high voltages of above 15 kV. In this case, the spiral pulse generators generally include two conductors of approximately equal lengths which are wound in the form of spirals; see FIG. 1. This means that each conductor has approximately the same number of turns. Such a design is necessary in order to use the vector inversion principle.

DE-Az 102006026750.8 has disclosed using a spiral pulse generator which is surrounded by a ferritic material with a relative permeability of μᵣ=1 to 5000. Explicit reference is made to these three specifications. These specifications always use the principle of a current which is flowing as a result of the short circuit in the first turn inducing a high-voltage pulse in the remaining turns.

In accordance with the invention, a considerably different length of the two wound conductors is now used. In this case, the second conductor only has a few turns, while the first conductor has the usual number of turns, such as from 20 to 100, for example. In this case, the spiral pulse generator acts as a transformer which can withstand high temperatures. This transformer functions in similar fashion to an integrated autotransformer by virtue of the second conductor acting as a capacitor and therefore as a charging capacitor for the transformer. By virtue of this second conductor being shortened, either the physical shape can be reduced in size or the transformer can be designed to have more turns given the same volume, which results in a higher high-voltage pulse.

When using a separate conventional charging capacitor, the generator can also be designed to have only one conductor winding with three contacts as a genuine autotransformer.

The spiral pulse generator now used is in particular a so-called LTCC component part or else HTCC component part. This material is a special ceramic which can be made to withstand temperatures of up to 600° C. Although LTCC has already been used in connection with lamps (see US 2003/0001519 and U.S. Pat. No. 6,853,151), it was used for entirely different purposes in lamps with virtually hardly any temperature loading, with typical temperatures of below 100° C. The particular value of the high temperature stability of LTCC in connection with the starting of high-pressure discharge lamps, primarily metal-halide lamps with starting problems, has not been discussed in the prior art.

The spiral pulse generator, in terms of its basic design, is a component which combines properties of a capacitor with those of a waveguide for producing starting pulses with a voltage of at least 1.5 kV. In order to produce such a spiral pulse generator, two ceramic “green films” with a metallic conductive paste are printed and then wound in offset fashion to form a spiral and finally isostatically pressed to form a molding. The following co-sintering of metal paste and ceramic film takes place in air in a temperature range between 800 and 900° C. This processing allows a use range of the spiral pulse generator of up to 700° C. temperature loading. As a result, the spiral pulse generator can be accommodated in the direct vicinity of the discharge vessel in the outer bulb, but also in the base or in the direct vicinity of the lamp.

Irrespective of this, such a spiral pulse generator can also be used for other applications because it is not only stable at high temperatures, but is also extremely compact. It is essential for this that the spiral pulse generator is in the form of an LTCC component part, including ceramic films and metallic conductive paste. In order to generate a sufficient output voltage, the spiral should include at least 5 turns.

In addition, it is possible on the basis of this high-voltage pulse generator to specify a starting unit which furthermore includes at least one charging resistor and a switch. The switch may be a spark gap or else a diac using SiC technology.

In the case of an application for lamps, it is preferred to accommodate the spiral pulse generator in the outer bulb. This is because there is therefore no longer a need for a voltage feed line which withstands high voltages.

In addition, a spiral pulse generator can be dimensioned in such a way that the high-voltage pulse even makes possible hot restarting of the lamp. The dielectric including ceramic is characterized by an extremely high dielectric constant ε of ε>10, where an ε of typically 70, up to ε=100 can be reached, depending on the material and design. This provides a very high capacitance of the spiral pulse generator and makes possible a comparatively large time span of the pulses produced. This makes a very compact design of the spiral pulse generator possible, with the result that installation in conventional outer bulbs of high-pressure discharge lamps is successful. Furthermore, the high-voltage pulse produced makes available a comparatively large amount of energy, which, after successful flashover, facilitates the transition to automatic discharge.

The large pulse width also facilitates the flashover in the discharge volume.

Any conventional glass can be used as the material of the outer bulb of a lamp, i.e. in particular hard glass, vycor or quartz glass. The choice of fill is not subject to any particular restriction either.

### BRIEF DESCRIPTION OF THE DRAWINGS

The invention will be explained in more detail below with reference to a plurality of exemplary embodiments. In the figures:

FIG. 1 shows the basic design of a spiral pulse generator as is already known;

FIG. 2 shows the basic design of a spiral pulse generator with a ferritic enclosure;

FIG. 3 shows the basic design of a spiral pulse generator with a shortened second conductor;

FIG. 4 shows the basic design of a spiral pulse generator with only one metallic conductor;

FIG. 5 shows the basic design of a metal-halide lamp with a spiral pulse generator in the outer bulb;

FIG. 6 shows a metal-halide lamp with a spiral pulse generator in the outer bulb;

FIG. 7 shows a metal-halide lamp with a spiral pulse generator in the base.

### PREFERRED EMBODIMENT OF THE INVENTION

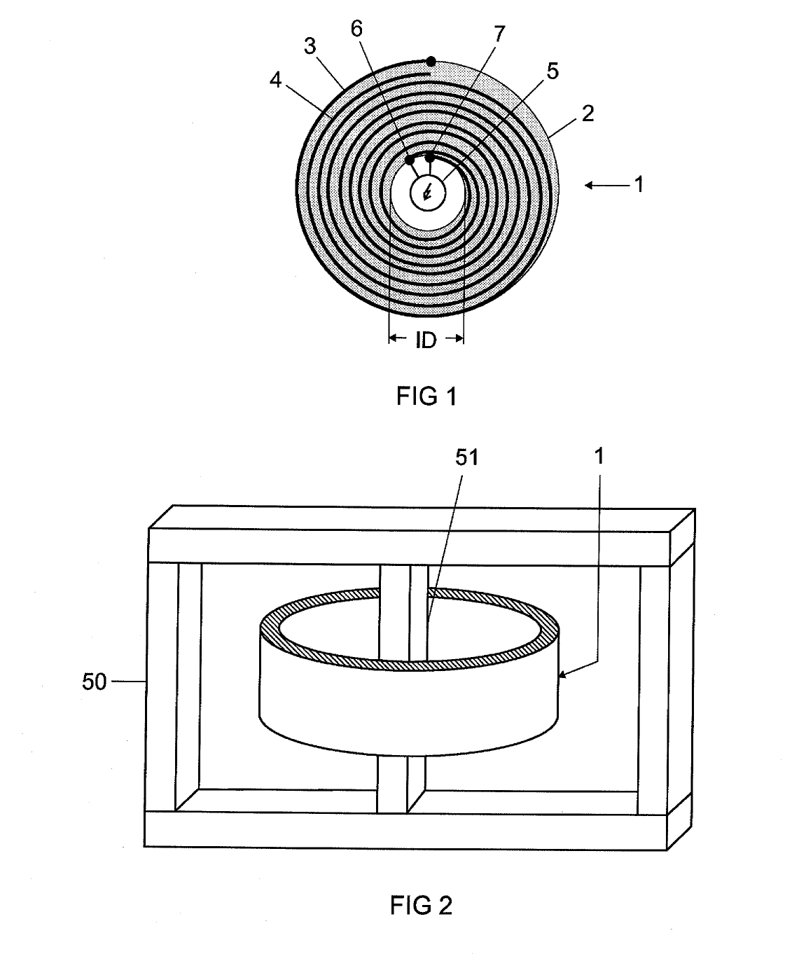

FIG. 1 shows the basic design of a spiral pulse generator 1 in a plan view. It includes a ceramic cylinder 2, into which two different metallic conductors 3 and 4 have been wound as a strip of film in the form of spirals. The cylinder 2 is hollow on the inside and has a given inner diameter ID. The two inner contacts 6 and 7 of the two conductors 3 and 4 are as close to one another as possible and are connected to one another via a spark gap 5.

Only the outer of the two conductors has a further contact 8 at the outer periphery of the cylinder. The other conductor ends open. The two conductors thereby together form a waveguide in a dielectric medium, the ceramic.

The spiral pulse generator is either wound from two ceramic films coated with metal paste or constructed from two metal films and two ceramic films. An important characteristic in this case is the number n of turns, which should preferably be of the order of magnitude of 5 to 100. This winding arrangement is then laminated and subsequently sintered, as a result of which an LTCC component part is produced. The spiral pulse generators thus produced with a capacitor property are then connected to a spark gap and a charging resistor.

The spark gap can be located at the inner or the outer connections or else within the winding of the generator. A spark gap which is temperature-resistant can preferably be used as the high-voltage switch which initiates the pulse. A semiconductor switching element, preferably using SiC technology, can also be used. This is suitable for temperatures of above 350° C.

In a specific exemplary embodiment, a ceramic material with ε=60 to 70 is used. In this case, a ceramic film, in particular a ceramic tape such as Heratape CT 707 or preferably CT 765 or else a mixture of the two, in each case by Heraeus, is preferably used as the dielectric. It has a thickness of the green film of typically from 50 to 150 μm. In particular, Ag conductive paste such as “cofirable silver”, likewise by Heraeus, is used as the conductor. A specific example is TC 7303 by Heraeus. Good results are also produced by the metal paste 6145 by DuPont. These parts can be laminated easily and then baked (“binder burnout”) and cosintered (“co-firing”).

In one exemplary embodiment, the inner diameter ID of the spiral pulse generator is 10 mm. The width of the individual strips is likewise 10 mm. The film thickness is 50 μm and also the thickness of the two conductors is in each case 50 μm. The charging voltage is 300 V. With these preconditions, the spiral pulse generator reaches an optimum for its properties given a turns number of n=20 to 70.

The generator is surrounded by a ferritic E-I core with a permeability of μ=50 . . . 5000, as is shown in the figure. As a result, it is operated as a transformer and not in accordance with the vector inversion principle.

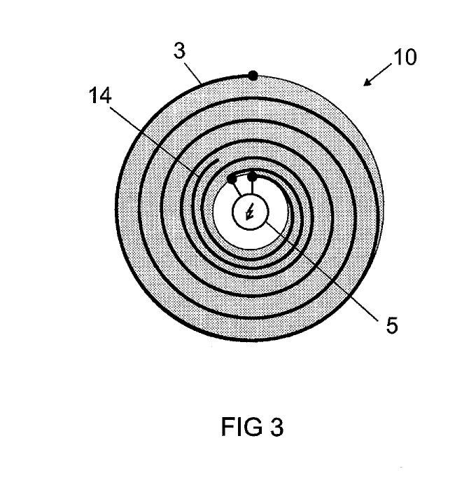

Advantageously, the generator 1 is entirely or partially surrounded by a ferritic material 50 with a permeability of μ=50 to 5000. FIG. 2 shows a ferrite 50 with an E core configuration, whose central bar 51 passes through the inner cavity of the generator 1.

FIG. 3 shows a spiral pulse generator 10 according to the invention in which the second metallic conductor 14 is considerably shorter than the first conductor 3. The second conductor 14 should in particular be at least 5 turns or at least 10% of the number of turns shorter than the first conductor 3, whose turns number is preferably of the order of magnitude of n=20 to 100. The contacts of the spark gap 5 can in this case lie opposite one another or be as close by one another as possible.

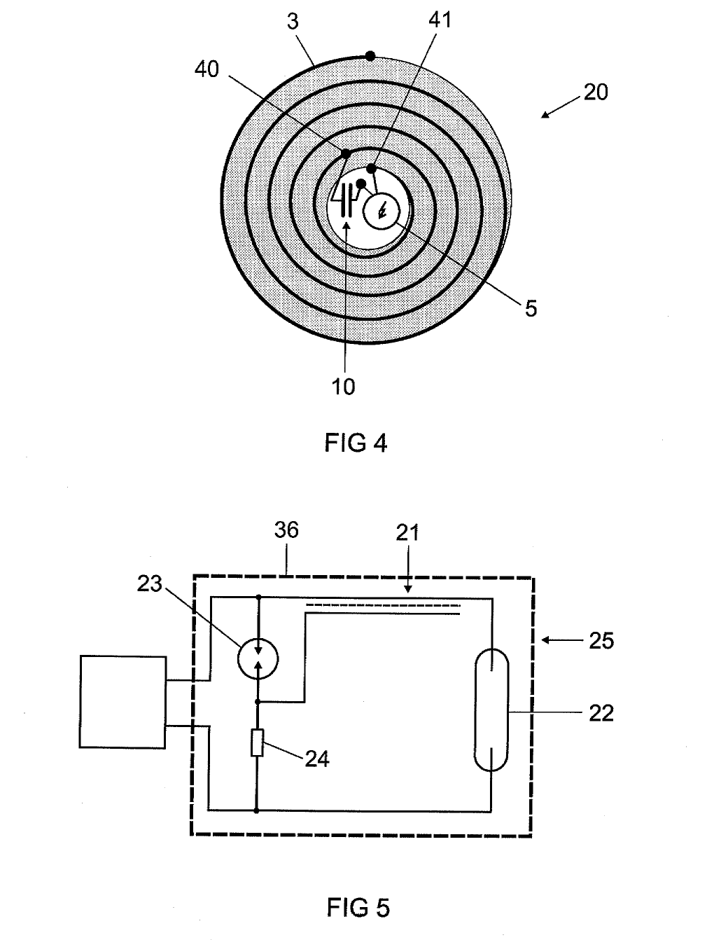

FIG. 4 shows a spiral pulse generator 20 which has only a single metallic conductor 3. It now has a separate conventional charging capacitor 10, which is connected in series with the spark gap 5. This circuit acts as an autotransformer by virtue of a center tap 40 of the metallic conductor being connected to the inner end 41 of the metallic conductor via the charging capacitor 10 and the spark gap 5.

FIG. 5 shows the basic design of a metal-halide lamp 25 with an integrated spiral pulse generator 21, with no starting electrode being fitted on the outside of the discharge vessel 22, which can be manufactured from quartz glass or ceramic. The spiral pulse generator 21 is accommodated with the spark gap 23 and the charging resistor 24 in the outer bulb 36.

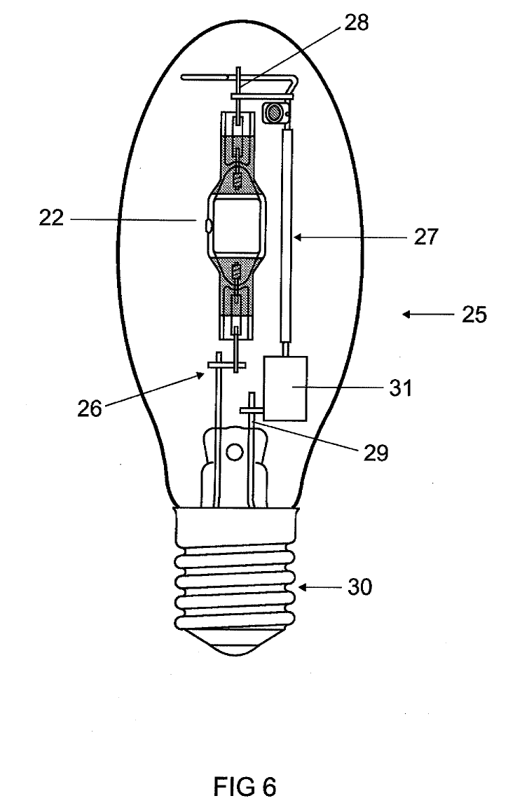

FIG. 6 shows a metal-halide lamp 25 with a discharge vessel 22, which is held by two feed lines 26, 27 in an outer bulb. The first feed line 26 is a wire with a short-angled bend. The second feed line 27 is substantially a bar, which leads to the leadthrough 28 remote from the base. A starting unit 31, which contains the spiral pulse generator, the spark gap and the charging resistor, is arranged between the feed line 29 emerging from the base 30 and the bar 27, as indicated in FIG. 5.

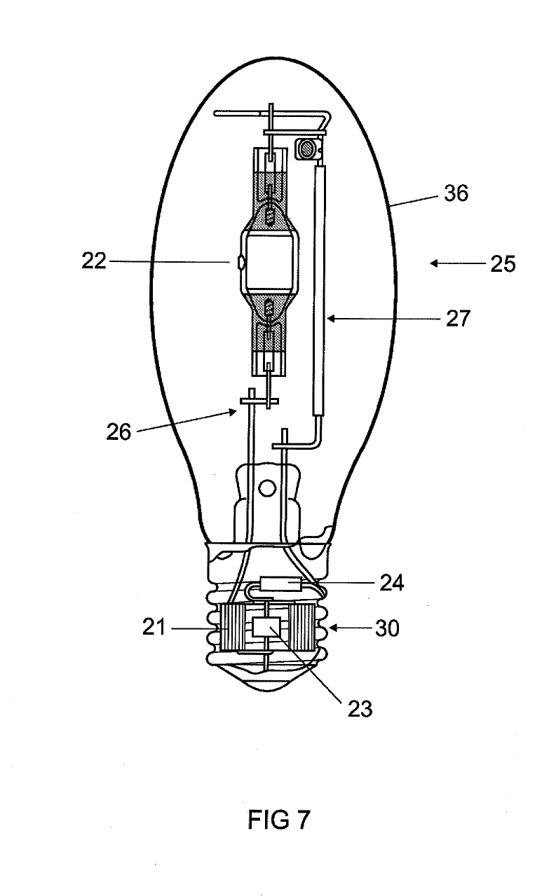

FIG. 7 shows a metal-halide lamp 25 similar to that in FIG. 5 with a discharge vessel 22, which is held by two feed lines 26, 27 in an outer bulb 36. The first feed line 26 is a wire with a short-angled bend. The second feed line 27 is substantially a bar, which leads to the leadthrough 28 remote from the base. In this case, the starting unit is arranged in the base 30, to be precise both the spiral pulse generator 21 and the spark gap 23 and the charging resistor 24.

This technology can also be applied for electrodeless lamps, with the spiral pulse generator being capable of acting as the starting aid.

Further applications of this compact high-voltage pulse generator consist in the starting of other devices. The application is primarily advantageous in the case of so-called magic spheres, in the generation of X-ray pulses and the generation of electron beam pulses. A use in motor vehicles as a replacement for the conventional ignition coils is also possible.

In this case, turns numbers of n up to 500 are used, with the result that the output voltage reaches up to the order of magnitude of 100 kV. This is because the output voltage U_{A} is given, as a function of the charging voltage U_{L}, by U_{A}=2×n×U_{L}×η, where the efficiency η is given by η=(AD-ID)/AD.

The invention demonstrates particular advantages when used with high-pressure discharge lamps for automobile headlamps which are filled with xenon under a high pressure of preferably at least 3 bar and metal halides. These lamps are particularly difficult to start since the starting voltage is more than 10 kV owing to the high xenon pressure. At present, attempts are being made to accommodate the components of the starting unit in the base. A spiral pulse generator with an integrated charging resistor can be accommodated in the base of the motor vehicle lamp.

The invention demonstrates very particular advantages when used with high-pressure discharge lamps which do not contain any mercury. Such lamps are particularly desirable for reasons of environmental protection. They contain a suitable metal halide fill and in particular a noble gas such as xenon under a high pressure. Owing to the lack of mercury, the starting voltage is particularly high. It is more than 20 kV. At present, attempts are being made to accommodate the components of the starting unit in the base. A spiral pulse generator with an integrated charging resistor can be accommodated either in the base of the mercury-free lamp or in an outer bulb of the lamp.

1. A compact high-voltage pulse generator based on a spiral pulse generator, the spiral pulse generator being in the form of an LTCC component part or HTCC component part comprising a ceramic film wound in the form of a spiral and metallic conductive paste applied thereto in strip form, wherein the spiral pulse generator acts as a transformer by virtue of a first metallic conductor being rolled up to form a spiral with n turns, where n is at least 5, while in addition a switch and a charging capacitor are connected to the start of the first metallic conductor.

2. The high-voltage pulse generator as claimed in claim 1, wherein the spiral pulse generator is connected in the form of an autotransformer by virtue of it having only one single metallic conductor, and a center tap of the metallic conductor is connected via the charging capacitor and the spark gap to the inner end of the metallic conductor.

3. The high-voltage pulse generator as claimed in claim 1, wherein the spiral comprises at most n=500 turns.

4. The high-voltage pulse generator as claimed in claim 1, wherein the generator is entirely or partially surrounded by a ferritic material with a permeability of μ=50 . . . 5000.

5. The high-voltage pulse generator as claimed in claim 1, wherein the switch is a spark gap.

6. The high-voltage pulse generator as claimed in claim 1, wherein the charging capacitor is a conventional capacitor.

7. The high-voltage pulse generator as claimed in claim 1, wherein the charging capacitor is formed by virtue of the fact that a second metallic conductor is wound on a second ceramic film, which is wound in the form of a spiral, together with the first ceramic film, but the wound length of the second ceramic film is at least two windings shorter than the wound length of the first ceramic film.

8. The high-voltage pulse generator as claimed in claim 1, wherein the number of windings of the second metallic conductor is at least one winding and at most 20% of the number of windings of the first metallic conductor.

9. A starting device based on a spiral pulse generator as claimed in claim 1, wherein the starting device furthermore comprises at least one charging resistor and a switch.

10. A high-pressure discharge lamp with a discharge vessel which is accommodated in an outer bulb, a starting device being integrated in the lamp which produces high-voltage pulses in the lamp of at least 15 kV, wherein the starting device is accommodated in the outer bulb and comprises a high-voltage pulse generator, wherein the high-voltage pulse generator is based on a spiral pulse generator, the spiral pulse generator being in the form of an LTCC component part or HTCC component part comprising a ceramic film wound in the form of a spiral and metallic conductive paste applied thereto in strip form, wherein the spiral pulse generator acts as a transformer by virtue of a first metallic conductor being rolled up to form a spiral with n turns, where n is at least 5, while in addition a switch and a charging capacitor are connected to the start of the first metallic conductor.

11. The high-pressure discharge lamp as claimed in claim 10, wherein the starting device is held in the outer bulb by a frame.

12. The high-pressure discharge lamp as claimed in claim 10, wherein the high voltage produced by the spiral pulse generator acts directly on two electrodes in the discharge vessel.

13. The high-pressure discharge lamp as claimed in claim 10, wherein the voltage produced by the spiral pulse generator acts on an auxiliary starting electrode fitted on the outside of the discharge vessel.

14. The high-pressure discharge lamp as claimed in claim 10, wherein the spiral pulse generator comprises a plurality of layers, the number n of layers being at least n=5.

15. The high-pressure discharge lamp as claimed in claim 14, wherein the number n of layers is at most n=500.

16. The high-pressure discharge lamp as claimed in claim 10, wherein the spiral pulse generator has an approximately hollow-cylindrical design, with an inner diameter of at least 10 mm.

17. The high-pressure discharge lamp as claimed in claim 10, wherein the dielectric constant ε of the spiral pulse generator is at least ε=10.

18. The high-pressure discharge lamp as claimed in claim 10, wherein, in addition, a series resistor is accommodated in the outer bulb, which series resistor limits the charging current of the spiral pulse generator.

19. A high-pressure discharge lamp with a discharge vessel and a base, a starting device being integrated in the lamp which produces high-voltage pulses in the lamp of at least 15 kV, wherein the starting device is accommodated in the base of the lamp and comprises a high-voltage pulse generator, wherein the high-voltage pulse generator is based on a spiral pulse generator, the spiral pulse generator being in the form of an LTCC component part or HTCC component part comprising a ceramic film wound in the form of a spiral and metallic conductive paste applied thereto in strip form, wherein the spiral pulse generator acts as a transformer by virtue of a first metallic conductor being rolled up to form a spiral with n turns, where n is at least 5, while in addition a switch and a charging capacitor are connected to the start of the first metallic conductor.

20. The high-pressure discharge lamp as claimed in claim 15, wherein the number n of layers is at most n=100.
